(19) United States
(12) Patent Application Publication
(10) Pub. No.: US 2024/0063773 A1
(43) Pub. Date: Feb. 22, 2024

(54) MULTILAYER PIEZOELECTRIC SUBSTRATE PACKAGING

(71) Applicant: Skyworks Solutions, Inc., Irvine, CA (US)

(72) Inventors: Hironori Fukuhara, Ibaraki-Shi (JP); Rei Goto, Osaka-Shi (JP)

(21) Appl. No.: 18/234,832

(22) Filed: Aug. 16, 2023

Related U.S. Application Data
(60) Provisional application No. 63/398,744, filed on Aug. 17, 2022.

(51) Int. Cl. H03H 9/10; H03H 3/08; H03H 9/02

(52) U.S. Cl. CPC H03H 9/1092; H03H 3/08; H03H 9/02834; H03H 9/02897

(57) ABSTRACT

A surface acoustic wave filter package includes a cavity formed in or above a substrate and one or more surface acoustic wave filters formed on the substrate. The surface acoustic wave filter package includes a cavity roof including a filler material and having a low coefficient of thermal expansion.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Field

Embodiments of this disclosure relate to chip scale packages (CSPs), CSPs for acoustic wave devices, and in particular to CSPs for surface acoustic wave (SAW) filters with reduced thermal deformation.

### Description of the Related Technology

An acoustic wave filter can include a plurality of resonators arranged to filter a radio frequency signal. Example acoustic wave resonators include SAW resonators and bulk acoustic wave (BAW) resonators. A surface acoustic wave resonator can include an interdigital transductor (IDT) electrode on a piezoelectric substrate. The surface acoustic wave resonator can generate a surface acoustic wave on a surface of the piezoelectric layer on which the interdigital transductor electrode is disposed. In BAW resonators, acoustic waves propagate in a bulk of a piezoelectric layer. Example BAW resonators include film bulk acoustic wave resonators (FBARs) and solidly mounted resonators (SMRs).

Acoustic wave filters can be implemented in radio frequency electronic systems. For instance, filters in a radio frequency front end of a mobile phone can include acoustic wave filters. An acoustic wave filter can be a band pass filter. A plurality of acoustic wave filters can be arranged as a multiplexer. For example, three acoustic wave filters can be arranged as a triplexer. As another example, four acoustic wave filters can be arranged as a quadplexer.

Multilayer piezoelectric substrate (MPS) packaging methods are developing to provide for high Q, high K², low TCF and high power durability filter solutions. A consolidated packaging method is required for mass production. In temperature compensated (TC) SAW technology, CSPs use a silicon (Si) substrate and comprise a copper (Cu) shielding in the package (PKG) structure. In such packages, thermal stress is strong.

### BRIEF DESCRIPTION OF THE DRAWINGS

FIG. 1A is a cross sectional view of a TCSAW device.

FIG. 1B is a top view of the TCSAW device of FIG. 1A.

FIG. 2A is a cross sectional view of a design of a chip scale package (CSP) for an acoustic wave device built on a substrate that may exhibit deficiencies due to deformations under thermal stress.

FIG. 2B is a cross sectional view of a portion of a design of a chip scale package (CSP) according to FIG. 2A built on a silicon (Si) substrate with a coefficient of thermal expansion (CTE) of 3.3 ppm/° illustrating a simulation of the scaled (×10) deformation of said portion under thermal stress in the temperature range between −50° C. and 160° C.

FIG. 2C is a cross sectional view of a portion of a design of a chip scale package (CSP) according to FIG. 2A built on a Lithium niobate (LiNbO₃ or LN) substrate with a CTE of 15 ppm/° illustrating a simulation of the scaled (×10) deformation of said portion under thermal stress in the temperature range between −50° C. and 160° C.

FIGS. 3A to 3C are cross sectional views of exemplary design of CSPs for acoustic wave devices built on a silicon Si substrate with reduced deformation under thermal stress.

FIG. 3D is a top view of an exemplary design of a CSP for acoustic wave device built on a silicon Si substrate with reduced deformation under thermal stress.

FIGS. 4A to 4D show results of simulations of the deformation for a CSP without a low CTE layer (A), a CSP with a low CTE layer with a CTE of 20 ppm/° and a thinner Cu layer (B), a CSP with a low CTE layer with a CTE of 20 ppm/° and minimum Cu (C), and a CSP with a low CTE layer with a CTE of 10 ppm/° and minimum Cu (D).

FIG. 5 is a schematic diagram of a ladder filter according to an embodiment.

FIG. 6 is a schematic diagram of a ladder filter according to another embodiment.

FIG. 7 is a schematic diagram of a lattice filter.

FIG. 8 is a schematic diagram of a hybrid ladder and lattice filter.

FIG. 9 is a schematic diagram of an acoustic filter that includes ladder stages and a multi-mode surface acoustic wave filter.

FIG. 10A is a schematic diagram of a duplexer that includes an acoustic wave filter according to an embodiment.

FIG. 10B is a schematic diagram of a multiplexer that includes an acoustic wave filter according to an embodiment.

FIG. 11 is a schematic diagram of a radio frequency module that includes an acoustic wave filter according to an embodiment.

FIG. 12 is a schematic block diagram of a module that includes an antenna switch and duplexers according to an embodiment.

FIG. 13 is a schematic block diagram of a module that includes a power amplifier, a radio frequency switch, and duplexers according to an embodiment.

FIG. 14 is a schematic block diagram of a module that includes a low noise amplifier, a radio frequency switch, and filters according to an embodiment.

FIG. 15 is a schematic diagram of a radio frequency module that includes an acoustic wave filter according to an embodiment.

FIG. 16A is a schematic block diagram of a wireless communication device that includes an acoustic wave filter according to an embodiment.

FIG. 16B is a schematic block diagram of another wireless communication device that includes an acoustic wave filter according to an embodiment.

### DETAILED DESCRIPTION OF EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Acoustic filters can implement bandpass filters. For example, a bandpass filter can be formed from temperature compensated surface acoustic wave (TCSAW) resonators. As another example, a bandpass filter can be formed from bulk acoustic wave (BAW) resonators, such as film bulk acoustic wave resonators (FBARs).

In acoustic filter applications, insertion loss improvement is typically desired by customers. Insertion loss improvement can help a receive chain with achieve a desired noise figure. Insertion loss improvement can help with implementing a transmit chain with less power consumption and/or better power handling.

Aspects of this disclosure relate to implementing an acoustic wave filter from more than one type of acoustic resonator. In certain embodiments, an acoustic wave filter can include series TCSAW resonators and shunt BAW resonators. Series TCSAW resonators can achieve higher quality factor (Q) in a frequency range below a resonant frequency (fs), while shunt BAW resonators can achieve a higher Q in a frequency range between fs and an anti-resonant frequency (fp).

Compared to a BAW only acoustic wave filter, an acoustic wave filter with series TCSAW resonators and shunt BAW resonators can achieve better low channel insertion loss. Compared to a TCSAW only acoustic wave filter, an acoustic wave filter with series TCSAW resonators and shunt BAW resonators can achieve better overall insertion loss. Accordingly, an acoustic wave filter with series TCSAW resonators and shunt BAW resonators can achieve desirable insertion loss. Goto, R., Nakamura, H., and Hashimoto, K., J. Appl. Phys, 58, SGGC07, 2019, disclose the modeling of a transverse mode in temperature compensated surface acoustic waves (TCSAW) using a SiO₂/LiNbO₃ structure to meet insertion loss specifications using TCSAW devices employing a SiO₂-overlay/LiNbO₃ substrate structure.

In a TCSAW package employing a cavity, the cavity may be deflected under the weight of a Cu plate and the like disposed thereon. A characteristic of a filter may deteriorate, especially when the filter experiences some abutment due to a deflection. Several columns have been provided not only around the periphery of the cavity but also in the cavity; however, there has been some instability, in particular due heat or stress during production.

Providing a cavity per resonator will reduce the space formed over the IDTs to alleviate the characteristic deterioration due to the deflection. As a method of forming the cavity per resonator, a groove is formed on the substrate, an IDT is formed in the groove, and each resonator is surrounded by SiO2.

Example TCSAW devices will now be discussed.

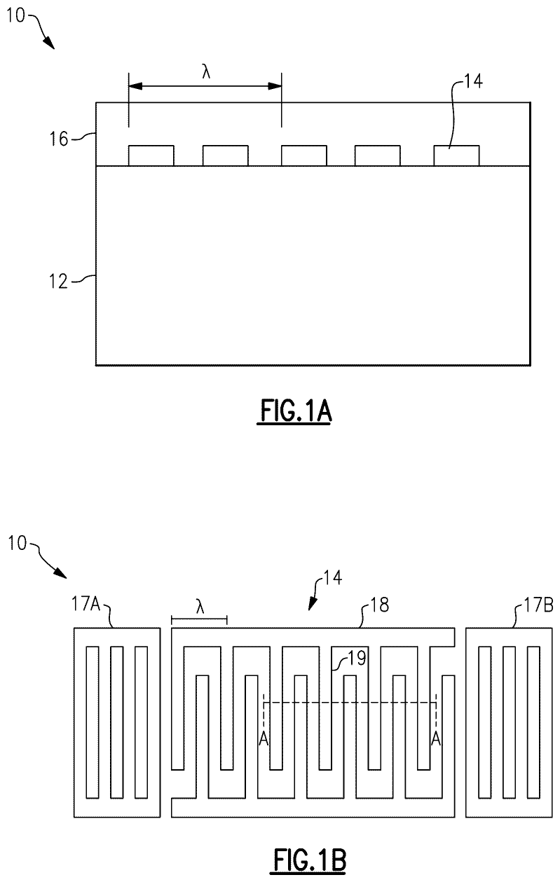

FIG. 1A is a cross sectional view of a TCSAW device 10. The TCSAW device 10 can be a TCSAW resonator. As illustrated, the TCSAW device 10 includes a piezoelectric layer 12, an interdigital transducer (IDT) electrode 14, and a temperature compensation layer 16 over the IDT electrode 14.

The piezoelectric layer 12 can be a lithium based piezoelectric layer. For example, the piezoelectric layer 12 can be a lithium niobate layer. As another example, the piezoelectric layer 12 can be a lithium tantalate layer.

In the TCSAW device 10, the IDT electrode 14 is over the piezoelectric layer 12. As illustrated, the IDT electrode 14 has a first side in physical contact with the piezoelectric layer 12 and a second side in physical contact with the temperature compensation layer 16. The IDT electrode 14 can include aluminum (Al), molybdenum (Mo), tungsten (W), gold (Au), silver (Ag), copper (Cu), platinum (Pt), ruthenium (Ru), titanium (Ti), the like, or any suitable combination or alloy thereof. The IDT electrode 14 can be a multi-layer IDT electrode in some applications.

In the TCSAW device 10, the temperature compensation layer 16 can bring a temperature coefficient of frequency (TCF) of the TCSAW device 10 closer to zero. The temperature compensation layer 16 can have a positive TCF. This can compensate for a negative TCF of the piezoelectric layer 12. The piezoelectric layer 12 can be lithium niobate or lithium tantalate, which both have a negative TCF. The temperature compensation layer 16 can be a dielectric film. The temperature compensation layer 16 can be a silicon dioxide layer. In some other embodiments, a different temperature compensation layer 16 can be implemented. Some examples of other temperature compensation layers include a tellurium dioxide (TeO2) layer or a silicon oxyfluoride (SiOF) layer.

FIG. 1B illustrates the IDT electrode 14 of the TCSAW device 10 of FIG. 1A in plan view. The view of the TCSAW device 10 in FIG. 1A is along the dashed line from A to A in FIG. 1B. The temperature compensation layer 16 is not shown in FIG. 1B to focus on the IDT electrode 14. The IDT electrode 14 is positioned between a first acoustic reflector 17A and a second acoustic reflector 17B. The acoustic reflectors 17A and 17B are separated from the IDT electrode 14 by respective gaps. The IDT electrode 14 includes a bus bar 18 and IDT fingers 19 extending from the bus bar 18. The IDT fingers 19 have a pitch of λ. The TCSAW device 10 can include any suitable number of IDT fingers 19. The pitch λ of the IDT fingers 19 corresponds to a resonant frequency of the TCSAW device 10.

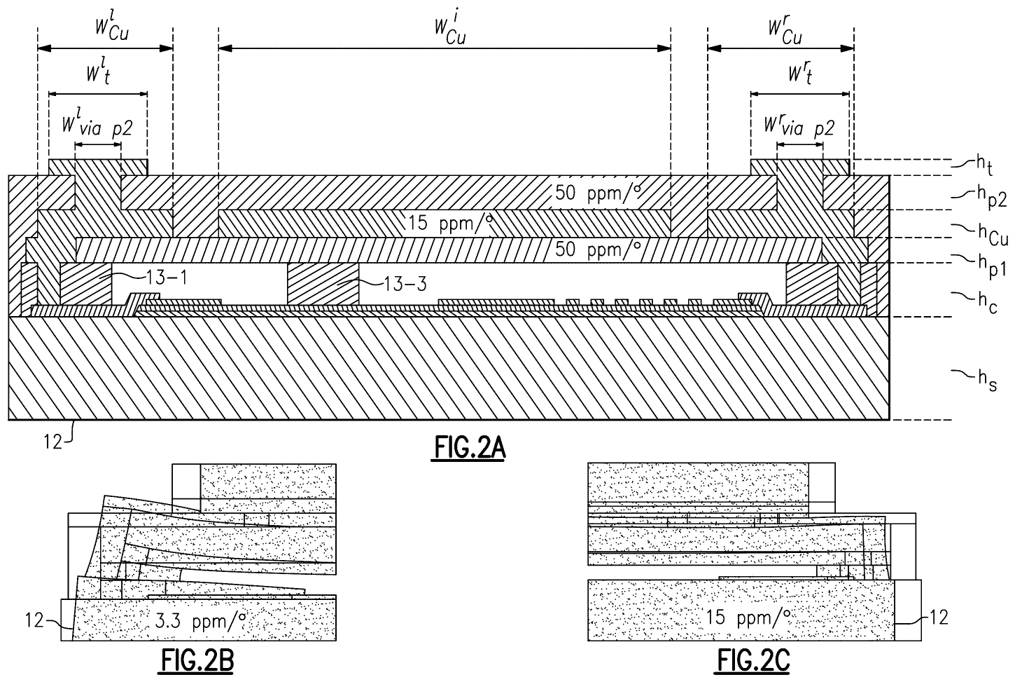

FIG. 2A is a cross sectional view of a design of a chip scale package (CSP) for an acoustic wave device built on a substrate that may exhibit deficiencies due to deformations under thermal stress.

The CSP of FIG. 2A comprises a support substrate 12. The support substrate may be formed from a silicon (Si) or from an other material. The Si substrate may have a coefficient of thermal expansion (CTE) of 3.3 ppm/°. The Si substrate has a height hₛ, where 80 μm≤hₛ≤200 μm, preferably hₛ=130 μm.

The CSP of FIG. 2A comprises a cavity formed on the support substrate 12. The cavity may comprise an acoustic wave device, preferably a temperature compensated (TC) acoustic wave filter, more preferably a TCSAW device. The cavity comprises a cavity wall 13-1 and may comprise a cavity pillar 13-3. The cavity has a height h_{c}, where 5 μm≤h_{c}≤20 μm, preferably h_{c}=12 μm, acoustic wave filter may be connected to an M2 layer on at least a part of the Si substrate forming an electrical signal line

The CSP of FIG. 2A may comprise a first polymer layer formed on, i.e. forming, the cavity. The first polymer layer may have a CTE of 50 ppm/° or more. The first polymer layer has a height hₚ₁, where 5 μm≤hₚ₁≤20 μm, preferably hₚ₁=12 μm.

The CSP of FIG. 2A may comprise a copper (Cu) layer formed on the first polymer layer. The Cu layer may have a CTE of 15 ppm/° or more. The Cu layer has a height h_{Cu}, where 10 μm≤h_{Cu}≤40 μm, preferably h_{Cu}=25 μm. The Cu layer may be connected to the M2 layer by a via through the first polymer layer and a via through the cavity wall 13-1. The Cu layer may have a plurality of separate portions. As shown in FIG. 2A, the Cu layer may have a left portion having a width w_{Cu}^{l}. The Cu layer may have a right portion having a width w_{Cu}^{r}. The Cu layer may have one (or more) intermediate portion(s) having a width w_{Cu}ⁱ. The left and the right portions may be connected to respective left and right via through the first polymer layer and left and right cavity pillars 13-1. The widths w_{Cu}^{l} and w_{Cu}^{r} may be the same or may be different.

The CSP of FIG. 2A may comprise a second polymer layer formed above the Cu layer. The second polymer layer may have a CTE of 50 ppm/° or more. The first second layer has a height hₚ₂, where 5 μm≤hₚ₂≤15 μm, preferably hₚ₂=10 μm.

The CSP of FIG. 2A may comprise one or more Cu terminals formed on the second polymer layer. A Cu terminal may have a height hₜ. A left Cu terminal may have a width wₜ^{l}. A right Cu terminal may have a width wₜ^{r}. The widths wₜ^{l} and wₜ^{r} may be the same or may be different.

A Cu terminal may be connected to a left or a right portion of the Cu layer by a via through the second polymer layer. A left via through the second polymer layer may have a width w_{via p2}^{l}. A right via through the second polymer layer may have a width w_{via p2}^{r}. The widths w_{via p2}^{l} and w_{via p2}^{r} may be the same or may be different.

Current CSP may crack due to strong deformation under thermal stress.

FIG. 2B is a cross sectional view of a portion of a design of a chip scale package (CSP) according to FIG. 2A built on a silicon (Si) substrate with a coefficient of thermal expansion (CTE) of 3.3 ppm/° illustrating a simulation of the scaled (×10) deformation of said portion under thermal stress in the temperature range between −50° C. and 160° C.

FIG. 2C is a cross sectional view of a portion of a design of a chip scale package (CSP) according to FIG. 2A built on a Lithium niobate (LiNbO₃ or LN) substrate with a coefficient of thermal expansion (CTE) of 15 ppm/° illustrating a simulation of the scaled (×10) deformation of said portion under thermal stress in the temperature range between −50° C. and 160° C.

As can be seen from FIG. 2B, FIG. 2C, and the CTEs of the layers shown in FIG. 2A, differences between coefficients of thermal expansion (CTEs) of the substrate and package cause large deformation. It is a goal of the present invention to provide a package structure with low deformation under thermal stress and providing said package structure at low costs.

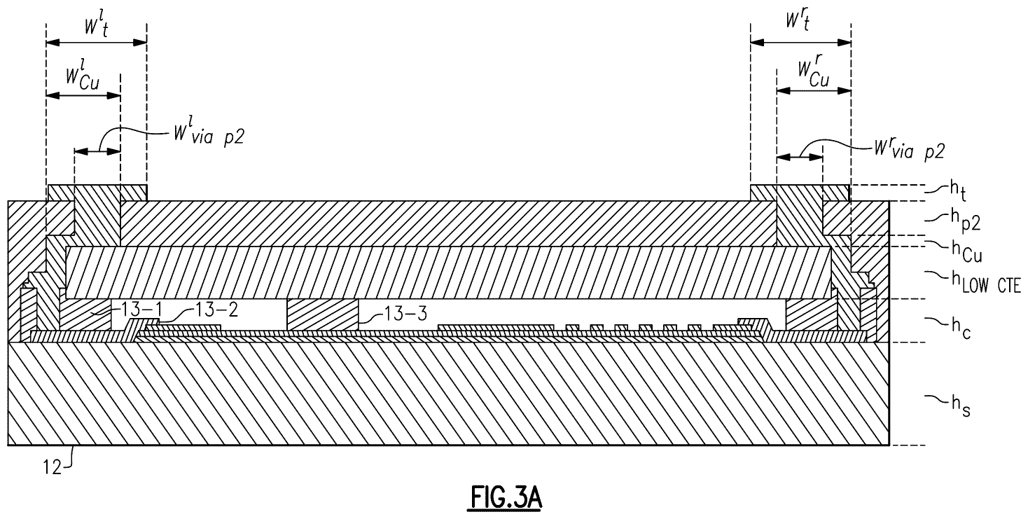

FIG. 3A is an exemplary design of a CSP for acoustic wave device built on a silicon Si substrate with reduced deformation under thermal stress.

As compared to the CSP shown in FIG. 2A, the first polymer layer of FIG. 2A and at least a portion of the Cu layer of FIG. 2A are essentially replaced by a layer of a polymer with a filler material having a low CTE, e.g. in the range between 0 and 30 ppm/°, and a high Young modulus. The Young modulus may be in the range between 5 and 30 Terapascal (TPa). A silica filler polymer may be used, for example.

Such a low CTE layer is used as a cavity roof. Piezo layer and functional layer (SiO₂) may be removed on the edge of the dies to prevent delamination. A Cu plate area may be minimized to avoid thermal deformation.

The CSP of FIG. 3A comprises a support substrate 12. The support substrate may be formed from a silicon (Si) or from an other material. The Si substrate may have a coefficient of thermal expansion (CTE) of 3.3 ppm/°. The Si substrate has a height hₛ, where 80 μm≤hₛ≤200 μm, preferably hₛ=130 μm.

The CSP of FIG. 3A comprises a cavity formed on the support substrate 12. The cavity may comprise an acoustic wave device, preferably a temperature compensated (TC) acoustic wave filter, more preferably a TCSAW device. The cavity comprises a cavity wall 13-1 and may comprise a cavity pillar 13-3. The cavity has a height h_{c}, where 5 μm≤h_{c}≤20 μm, preferably h_{c}=12 μm, acoustic wave filter may be connected to an M2 layer on at least a part of the Si substrate forming an electrical signal line. The cavity wall 13-1 may not touch a piezo and functional thin layer (SiO₂) of the acoustic wave device to prevent delamination by cavity wall stress. Cavity pillars 13-3 may be separated from cavity walls 13-1 to decouple stress of cavity walls 13-1 and pillars 13-3. A plurality of LT/SiO₂ edges may be covered by a M2 layer 13-2. M2 may be used as mechanical clamp of LT/SiO₂ to avoid delamination. M2 may be thicker as compared to the CSP shown in FIG. 2A, for instance 2 to 4 μm. M2 may be also used as electrical signal line. The cavity may be filled to increase a mechanical stability of the CSP.

The CSP comprises the low CTE layer formed above, e.g. forming, the cavity. The low CTE layer may have a CTE of less than 50 ppm/°. The low CTE layer has a height h_{low CTE}, where 5 μm≤h_{low CTE}≤20 μm, preferably h_{low CTE}=12 μm.

The CSP may comprise a copper (Cu) layer formed on the low CTE layer. The Cu layer may have a CTE of 15 ppm/° or more. The Cu layer has a height h_{Cu}, where 5 μm≤h_{Cu}≤40 μm, preferably h_{Cu}=10 μm. As compared to the CSP of FIG. 2A, the height h_{Cu} may be smaller.

The Cu layer may be connected to the M2 layer by a via through the first polymer layer and a via through the cavity wall 13-1. As compared to the CSP of FIG. 2A, Cu connections between the terminal to M2 may be thinner (cf. FIG. 3A and FIG. 3B) to reduce stress by thermal extension of Cu. Cu via may, in addition or alternatively, also be shorter (cf. FIG. 3C). Cu vias extending through different layers may at least pairwise be relatively arranged along a straight line. A minimum area of Cu may be located to achieve signal connection for a filter. Less Cu area may result in less thermal distortion. Mechanical stability may be achieved by forming the cavity roof with a filler material instead of a thick Cu plating.

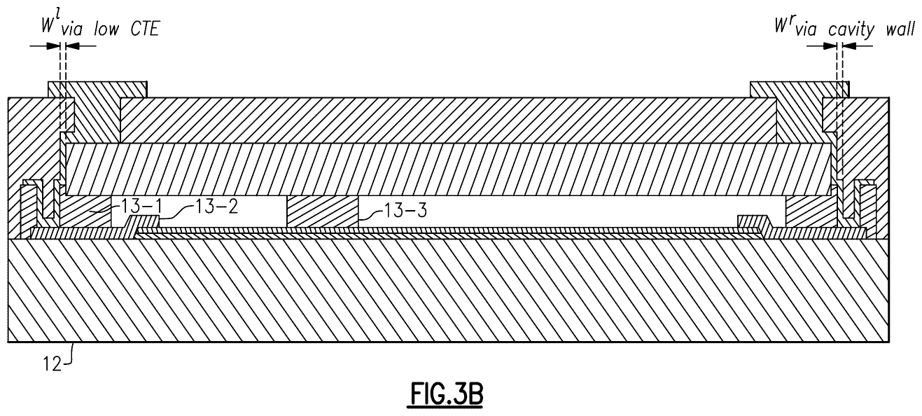

The Cu layer may have a plurality of separate portions. As shown in FIG. 3A, the Cu layer may have a left portion having a width w_{Cu}^{l}. The Cu layer may have a right portion having a width w_{Cu}^{r}. The Cu layer may have one (or more) intermediate portion(s) (not shown in FIG. 3A) having a width w_{Cu}ⁱ. The left and the right portions may be connected to respective left and right via through the first polymer layer and left and right cavity pillars 13-1. The widths w_{Cu}^{l} and w_{Cu}^{r} may be the same or may be different. The height of the one (or more) intermediate portion(s) may be smaller than a height of the left and/or a height of the right portion of the Cu layer. The CSP may have no intermediate portion (cf. FIG. 4C and FIG. 4D).

The CSP may comprise a second polymer layer formed above the Cu layer. The second polymer layer may have a CTE of less than 50 ppm/°. The first second layer has a height hₚ₂, where 5 μm≤hₚ₂≤15 μm, preferably hₚ₂=10 μm.

The CSP may comprise one or more Cu terminals formed on the second polymer layer. A Cu terminal may have a height hₜ, where 5 μm≤hₜ≤15 μm, preferably hₜ=10 μm. A left Cu terminal may have a width wₜ^{l}. A right Cu terminal may have a width wₜ^{r}. The widths wₜ^{l} and wₜ^{r} may be the same or may be different.

A Cu terminal may be connected to a left or a right portion of the Cu layer by a via through the second polymer layer. A left via through the second polymer layer may have a width w_{via p2}^{l}. A right via through the second polymer layer may have a width w_{via p2}^{r}. The widths w_{via p2}^{l} and w_{via p2}^{r} may be the same or may be different. As compared to the CSP of FIG. 2A, the widths w_{via p2}^{l} and w_{via p2}^{r} may be smaller.

FIG. 3B is an exemplary design of a CSP for acoustic wave device built on a silicon Si substrate with reduced deformation under thermal stress.

In the CSP according to FIG. 3B the Cu connection between the terminal and the M2 layer 13-3 are further reduced. A via at or through the low CTE layer has a width w_{via low CTE}^{l}. A via at or through the cavity wall 13-1 may have a width w_{via cavity wall}^{r}. The widths w_{via low CTE}^{l} and w_{via cavity wall}^{r} may be the same or may be different. The features of the CSP according to FIG. 3B may be combined with the features of the CSP according to FIG. 3A and vice versa.

FIG. 3C is an exemplary design of a CSP for acoustic wave device built on a silicon Si substrate with reduced deformation under thermal stress.

The CSP according to FIG. 3C has no second polymer layer formed above the Cu layer. Terminals may be formed directly on the low CTE layer. Cu vias extending through different layers are relatively arranged along a straight line. The terminal may or may not be shifted with respect to the straight line.

In the CSP according to FIG. 3C, a via at or through the low CTE layer hay a width w_{via low CTE}^{l}. A via at or through the cavity wall 13-1 may have a width w_{via cavity wall}^{r}. The widths w_{via low CTE}^{l} and w_{via cavity wall}^{r} may be the same or may be different.

The features of the CSP according to FIG. 3C may be combined with the corresponding features of the CSP according to FIG. 3A and FIG. 3B and vice versa.

FIG. 3D is a top view of an exemplary design of a CSP for acoustic wave device built on a silicon Si substrate with reduced deformation under thermal stress.

As shown in FIG. 3D, cavity pillars 13-3 may be separated from cavity walls 13-1 to decouple stress of cavity walls 13-1 and pillars 13-3. A plurality of LT/SiO₂ edges may be covered by a M2 layer 13-2. M2 may be used as mechanical clamp of LT/SiO₂ to avoid delamination. M2 may be also used as electrical signal line. The cavity may be filled to increase a mechanical stability of the CSP.

The features of the CSP according to FIG. 3D may be combined with the CSP according to FIG. 3A, FIG. 3B and FIG. 3C and vice versa.

FIG. 4A shows results of a simulation of the deformation for a CSP without a low CTE layer, such as the CSP shown in FIG. 2A.

FIG. 4B shows results of a simulation of the deformation for a CSP with a low CTE layer with a CTE of 20 ppm/°, a thinner Cu layer (w.r.t the Cu layer of the CSP in FIG. 4A) with an intermediate portion

FIG. 4C shows results of a simulation of the deformation for a CSP with a low CTE layer with a CTE of 20 ppm/° and minimum Cu (C) where the Cu layer has no intermediate portion.

FIG. 4D shows results of a simulation of the deformation for a CSP with a low CTE layer with a CTE of 10 ppm/° and minimum Cu (C) where the Cu layer has no intermediate portion.

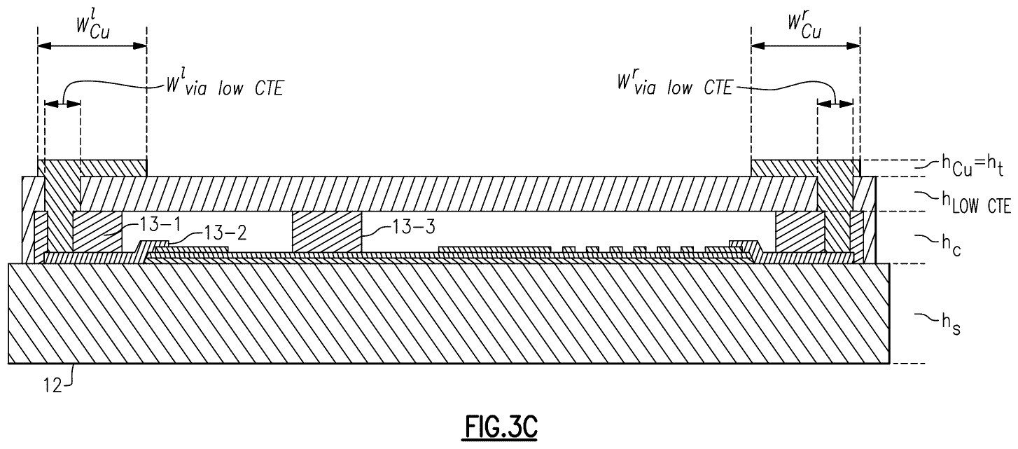

FIG. 5 is a schematic diagram of a ladder filter 50 according to an embodiment. The ladder filter 50 includes shunt BAW resonators 52 and series TCSAW resonators 54 coupled between RF input/output ports Port1 and Port2. The ladder filter 50 is an example topology of a band pass filter formed from acoustic resonators. In a band pass filter with a ladder filter topology, the shunt resonators can have lower resonant frequencies than the series resonators. The ladder filter 50 can be arranged to filter an RF signal. As illustrated, the shunt BAW resonators include resonators R1, R3, R5, R7, and R9. The illustrated series TCSAW resonators 54 include resonators R2, R4, R6, R8, and R10. In particular, the TC SAW resonators 54 may be formed with features of any one or more of the CSP shown in FIG. 2A, FIG. 3A to and/or FIG. 4D as described herein. The first RF input/output port Port1 can be a transmit port for a transmit filter or a receive port for a receive filter. The second RF input/output port Port2 can be an antenna port. Any suitable number of series acoustic resonators can be in included in a ladder filter. Any suitable number of shunt acoustic wave resonators can be included in a ladder filter.

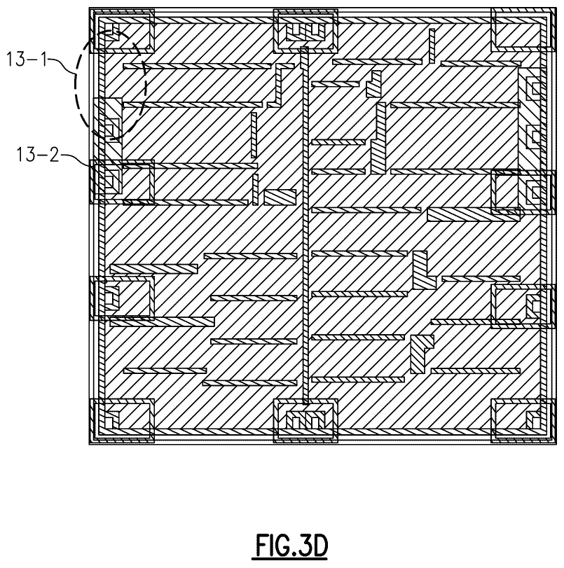

FIG. 6 is a schematic diagram of a ladder filter 60 according to another embodiment. The ladder filter 60 includes a plurality of acoustic resonators R1, R2, . . . , RN-1, and RN arranged between a first input/output port PORT1 and a second input/output port PORT1. One of the input/output ports PORT1 or PORT2 can be an antenna port. In certain instances, the other of the input/output ports PORT1 or PORT2 can be a receive port. In some other instances, the other of the input/output ports PORT1 or PORT2 can be a transmit port.

The ladder filter 60 illustrates that any suable number of ladder stages can be implemented in a ladder filter in accordance with any suitable principles and advantages disclosed herein. Ladder stages can start with a series resonator or a shunt resonator from any input/output port of the ladder filter 60 as suitable. As illustrated, the first ladder stage from the input/output port PORT1 begins with a shunt resonator R1. As also illustrated, the first ladder stage from the input/output port PORT2 begins with a series resonator RN.

The ladder filter 60 includes shunt resonators R1 and RN-1 and series resonator R2 and RN. The series resonators of the ladder filter 60 including resonators R2 and RN can be acoustic resonators of a first type that have higher Q than series resonators of a second type in a frequency range below fs. The shunt resonators of the ladder filter 60 including resonators R1 and RN-1 can be acoustic resonators of the second type and have higher Q than shunt resonators of the first type in a frequency range between fs and fp. This can lead to a reduced insertion loss. The ladder filter 60 can be a band pass filter with series resonators of the first type and shunt resonators of the second type. In some other embodiments, the series resonators of the ladder filter 60 including resonators R2 and RN can be acoustic resonators of the second type and the shunt resonators of the ladder filter 60 including resonators R1 and RN-1 can be acoustic resonators of the first type. In such embodiments, the ladder filter 60 can be a band pass filter.

The resonators of the first type can be TCSAW resonators and the resonators of the second type can be BAW resonators. Accordingly, the ladder filter 60 can include series TCSAW resonators and shunt BAW resonators in certain embodiments. Such BAW resonators can include FBARs and/or solidly mounted resonators (SMRs). In particular, the TCSAW resonators of the ladder filter 60 may be formed with features of any one or more of the CSP shown in FIG. 2A, FIG. 3A to and/or FIG. 4D as described herein.

The resonators of the first type can be multi-layer piezoelectric substrate (VIPS) SAW resonators and the resonators of the second type can be BAW resonators. Accordingly, the ladder filter 60 can include series MPS SAW resonators and shunt BAW resonators. Such BAW resonators can include FBARs and/or SMRs in certain embodiments.

The resonators of the first type can be non-temperature compensated SAW resonators and the resonators of the second type can be BAW resonators. Accordingly, the ladder filter 60 can include series non-temperature compensated SAW resonators and shunt BAW resonators in certain embodiments. Such BAW resonators can include FBARs and/or SMRs.

In a bandpass filter with a ladder filter topology, such as the acoustic wave filter 60, the shunt resonators can have lower resonant frequencies than the series resonators. In certain embodiments, the shunt resonators of the acoustic wave filter 60 are BAW resonators and the series resonators of the acoustic wave filter 60 are TCSAW resonators. In such embodiments, the acoustic wave filter 60 can be a band pass filter. Such a bandpass filter can achieve low insertion loss at both a lower band edge and an upper band edge of a passband.

In a band stop filter with a ladder filter topology, such as acoustic wave filter 60, the shunt resonators can have higher resonant frequencies than the series resonators. In certain embodiments, the acoustic wave filter 60 is a band stop filter, the shunt resonators of the acoustic wave filter 60 are TCSAW resonators and the series resonators of the acoustic wave filter 60 are BAW resonators. Such a band stop filter can achieve desirable characteristics in a stop band of the band stop filter.

In some applications of an acoustic wave filter that includes TC SAW series resonators and BAW shunt resonators, such as a transmit filter with a relatively high power handling specification, one or more series resonators close to a transmit port (or the lower frequency series resonators) can be BAW resonators to help with ruggedness.

In certain applications, the ladder filter 60 can be included in a multiplexer in which relatively high γ for the ladder filter 60 in one or more higher frequency carrier aggregation bands is desired. In such applications, an acoustic filter can include shunt resonators of the shunt type and an acoustic resonator of the second type can be included as a series resonator by which other series resonators of the first type are coupled to a common port of the multiplexer. This can increase γ of the ladder filter 60 in the one or more higher frequency carrier aggregation bands. For example, in applications where the second input/output port PORT2 is a common port of a multiplexer, the series resonator RN can be a BAW resonator, other series resonators of the ladder filter 60 can be TCSAW resonators, and the shunt resonators R1 and RN-1 can be BAW resonators. By having the series resonator RN closest to the common node be a BAW resonator instead of a TCSAW resonator, γ can be increased for the ladder filter 60 in one or more higher frequency carrier aggregation bands in such applications.

In some applications, the ladder filter 60 can be a transmit filter. In such applications, an acoustic resonator of the second type can be included as a series resonator by which other series resonators of the first type are coupled to a transmit port of the transmit filter. For example, in applications where the second input/output port PORT2 is a transmit port of a transmit filter, the series resonator RN can be a BAW resonator, other series resonators of the ladder filter 60 can be TCSAW resonators, and the shunt resonators R1 and RN-1 can be BAW resonators.

In certain applications, the ladder filter 60 can include more than two types of acoustic resonators. In such applications, the majority of the series resonators can be acoustic resonators of the first type (e.g., TCSAW resonators) and the majority of shunt resonators can be resonators of the second type (e.g., BAW resonators). The ladder filter 60 can include a third type of resonator as a shunt resonator and/or as a series resonator in such applications. The third type of resonator can be a Lamb wave resonator, for example. The acoustic wave filter 60 can include a plurality series resonators including temperature compensated surface acoustic wave resonators and a plurality shunt resonators including a Lamb wave resonator arranged as shunt resonator. The acoustic wave filter 60 can include a plurality of series resonators including a Lamb wave resonator and a plurality shunt resonators including bulk acoustic wave resonators arranged as shunt resonators.

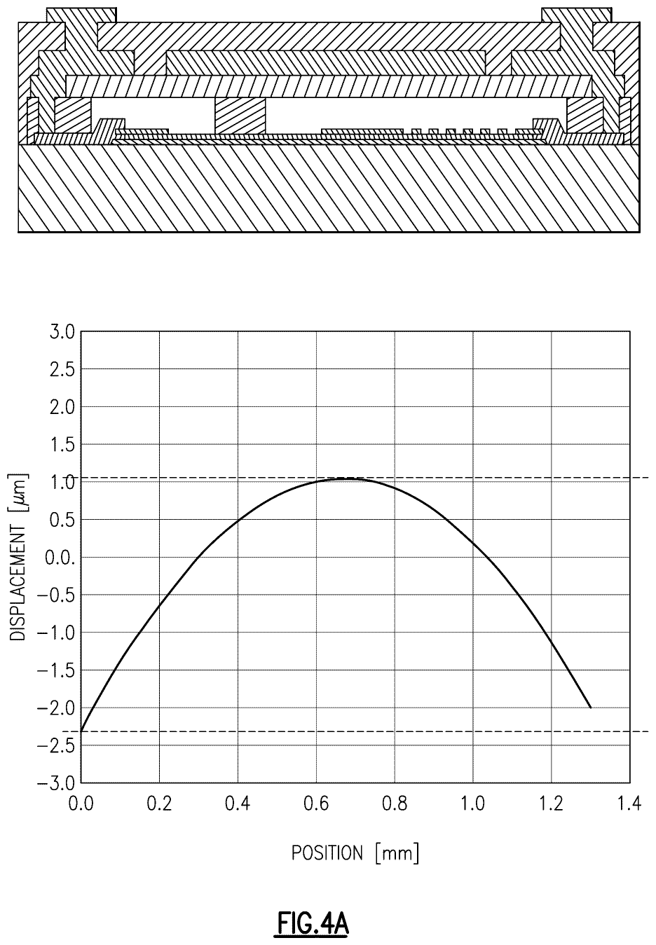

FIG. 7 is a schematic diagram of a lattice filter 70. The lattice filter 70 is an example topology of a band pass filter formed from acoustic wave resonators. The lattice filter 60 can be arranged to filter an RF signal. As illustrated, the lattice filter 70 includes acoustic wave resonators RL1, RL2, RL3, and RL4. The acoustic wave resonators RL1 and RL2 are series resonators. The acoustic wave resonators RL3 and RL4 are shunt resonators. The illustrated lattice filter 70 has a balanced input and a balanced output. The lattice filter 70 can be implemented with different type of acoustic resonators in accordance with any suitable principles and advantages disclosed herein. For example, the series resonators RL1 and RL2 can be TCSAW resonators and the shunt resonators RL3 and RL4 can be BAW resonators for a bandpass filter. In particular, the TC SAW resonators may be formed with features of any one or more of the CSP shown in FIG. 2A, FIG. 3A to and/or FIG. 4D as described herein.

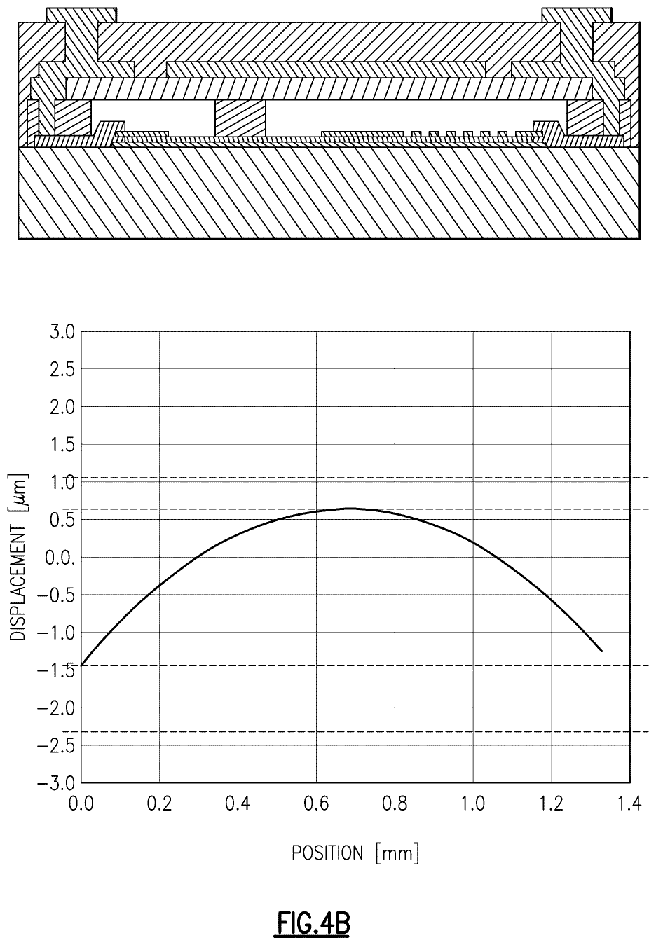

FIG. 8 is a schematic diagram of a hybrid ladder and lattice filter 80. The illustrated hybrid ladder and lattice filter includes series acoustic resonators RL1, RL2, RH3, and RH4 and shunt acoustic resonators RL3, RL4, RH1, and RH2. The hybrid ladder and lattice filter 80 can be implemented with different type of acoustic resonators in accordance with any suitable principles and advantages disclosed herein. For example, the series resonators RL1, RL2, RH3, and RH4 can be TCSAW resonators and the shunt resonators RL3, RL4, RH1, and RH2 can be BAW resonators for a bandpass filter. In particular, the TCSAW resonators may be formed with features of any one or more of the CSP shown in FIG. 2A, FIG. 3A to and/or FIG. 4D as described herein.

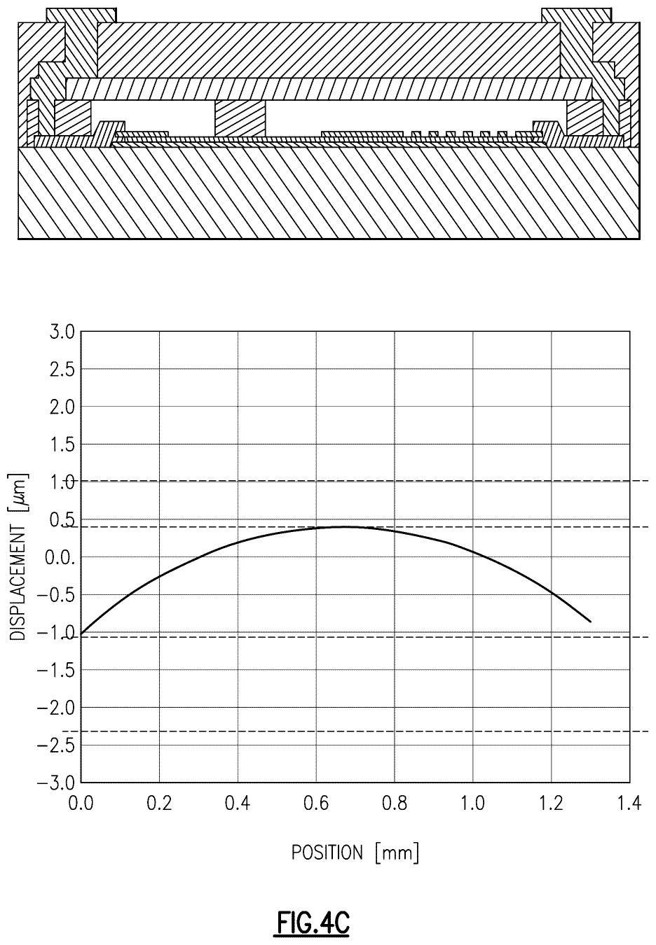

FIG. 9 is a schematic diagram of an acoustic filter 91 that includes ladder stages and a multi-mode surface acoustic wave filter 92. The illustrated acoustic filter 91 includes series resonators R2 and R4, shunt resonators R1 and R3, and multi-mode surface acoustic wave filter 92. The filter 91 can be a receive filter. The multi-mode surface acoustic wave filter 92 can be connected to a receive port. The multi-mode surface acoustic wave filter 92 includes longitudinally coupled IDT electrodes. The multi-mode surface acoustic wave filter 92 can include a temperature compensation layer over longitudinally coupled IDT electrodes in certain applications. The series resonators R2 and R4 can be TCSAW resonators and the shunt resonators R1 and R3 can be BAW resonators for a bandpass filter. The shunt resonators R1 and R3 being BAW resonators can help with lower skirt steepness and insertion loss. In particular, the TCSAW resonators may be formed with features of any one or more of the CSP shown in FIG. 2A, FIG. 3A to and/or FIG. 4D as described herein.

Acoustic filters disclosed herein include more than one type of acoustic wave resonator. Such filters can be implemented on a plurality of acoustic filter die. The plurality of acoustic filter die can be stacked and co-packaged with each other in certain applications.

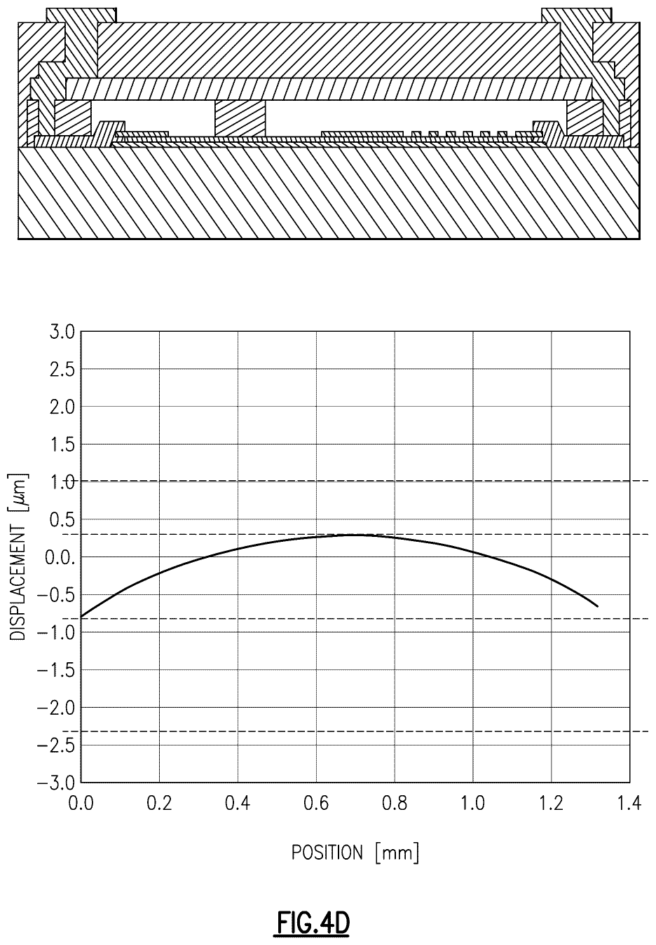

FIG. 10A is a schematic diagram of a duplexer 100 that includes an acoustic wave filter according to an embodiment. The duplexer 100 includes a first filter 102 and a second filter 104 coupled to together at a common node COM. One of the filters of the duplexer 100 can be a transmit filter and the other of the filters of the duplexer 100 can be a receive filter. The transmit filter and/or the receive filter can be respective ladder filters with acoustic wave resonators having a topology similar to the ladder filter 50 of FIG. 5 and the ladder filter 60 of FIG. 6. In some other instances, such as in a diversity receive application, the duplexer 100 can include two receive filters. The common node COM can be an antenna node.

The first filter 102 is an acoustic wave filter arranged to filter a radio frequency signal. The first filter 102 can include acoustic wave resonators coupled between a first radio frequency node RF1 and the common node. The first radio frequency node RF1 can be a transmit node or a receive node. The first filter 102 includes two types of acoustic resonators in accordance with any suitable principles and advantages disclosed herein.

The second filter 104 can be any suitable filter arranged to filter a second radio frequency signal. The second filter 104 can be, for example, an acoustic wave filter, an acoustic wave filter that includes two types of acoustic resonators, an LC filter, a hybrid acoustic wave LC filter, or the like. The second filter 104 is coupled between a second radio frequency node RF2 and the common node. The second radio frequency node RF2 can be a transmit node or a receive node.

Although example embodiments may be discussed with filters or duplexers for illustrative purposes, any suitable the principles and advantages disclosed herein can be implemented in a multiplexer that includes a plurality of filters coupled together at a common node. Examples of multiplexers include but are not limited to a duplexer with two filters coupled together at a common node, a triplexer with three filters coupled together at a common node, a quadplexer with four filters coupled together at a common node, a hexaplexer with six filters coupled together at a common node, an octoplexer with eight filters coupled together at a common node, or the like. One or more filters of a multiplexer can include an acoustic wave filter including two types of acoustic resonators in accordance with any suitable principles and advantages disclosed herein.

FIG. 10B is a schematic diagram of a multiplexer 105 that includes an acoustic wave filter according to an embodiment. The multiplexer 105 includes a plurality of filters 102 to 106 coupled together at a common node COM. The plurality of filters can include any suitable number of filters including, for example, 3 filters, 4 filters, 5 filters, 6 filters, 7 filters, 8 filters, or more filters. Some or all of the plurality of acoustic wave filters can be acoustic wave filters.

The first filter 102 is an acoustic wave filter arranged to filter a radio frequency signal. The first filter 102 can include acoustic wave resonators coupled between a first radio frequency node RF1 and the common node. The first radio frequency node RF1 can be a transmit node or a receive node. The first filter 102 includes two types of acoustic resonators in accordance with any suitable principles and advantages disclosed herein. The other filter(s) of the multiplexer 105 can include one or more acoustic wave filters, one or more acoustic wave filters that include two types of acoustic resonators in accordance with any suitable principles and advantages disclosed herein, one or more LC filters, one or more hybrid acoustic wave LC filters, or any suitable combination thereof.

The acoustic wave filters disclosed herein can be implemented in a variety of packaged modules. In particular, acoustic wave filters disclosed herein may be formed with features of any one or more of the CSP shown in FIG. 2A, FIG. 3A to and/or FIG. 4D as described herein. Some example packaged modules will now be disclosed in which any suitable principles and advantages of the acoustic wave filters and/or acoustic wave resonators disclosed herein can be implemented. The example packaged modules can include a package that encloses the illustrated circuit elements. A module that includes a radio frequency component can be referred to as a radio frequency module. The illustrated circuit elements can be disposed on a common packaging substrate. The packaging substrate can be a laminate substrate, for example. FIGS. 20 to 24 are schematic block diagrams of illustrative packaged modules according to certain embodiments. Any suitable combination of features of these packaged modules can be implemented with each other. While duplexers are illustrated in the example packaged modules of FIGS. 21, 22, and 24, any other suitable multiplexer that includes a plurality of filters coupled to a common node and/or standalone filter can be implemented instead of one or more duplexers. For example, a triplexer can be implemented in certain applications. As another example, one or more filters of a packaged module can be arranged as a transmit filter or a receive filter that is not included in a multiplexer.

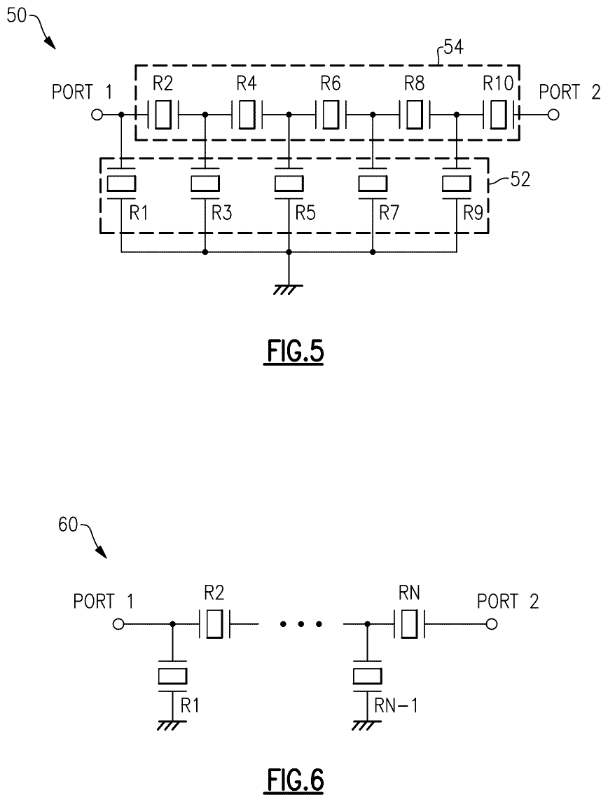

FIG. 11 is a schematic diagram of a radio frequency module 200 that includes an acoustic wave component 202 according to an embodiment. The illustrated radio frequency module 200 includes the acoustic wave component 202 and other circuitry 203. The acoustic wave component 202 can include one or more acoustic wave filters in accordance with any suitable combination of features of the acoustic wave filters disclosed herein. The acoustic wave component 202 can include an acoustic wave filter with series TCSAW resonators and shunt BAW resonators, for example.

The acoustic wave component 202 shown in FIG. 11 includes one or more acoustic wave filters 204 and terminals 205A and 205B. The one or more acoustic wave filters 204 includes an acoustic wave filter implemented in accordance with any suitable principles and advantages disclosed herein. The terminals 205A and 204B can serve, for example, as an input contact and an output contact. Although two terminals are illustrated, any suitable number of terminals can be implemented for a particular application. The acoustic wave component 202 and the other circuitry 203 are on a common packaging substrate 206 in FIG. 11. The package substrate 206 can be a laminate substrate. The terminals 205A and 205B can be electrically connected to contacts 207A and 207B, respectively, on the packaging substrate 206 by way of electrical connectors 208A and 208B, respectively. The electrical connectors 208A and 208B can be bumps or wire bonds, for example.

The other circuitry 203 can include any suitable additional circuitry. For example, the other circuitry can include one or more radio frequency amplifiers (e.g., one or more power amplifiers and/or one or more low noise amplifiers), one or more radio frequency switches, one or more additional filters, one or more RF couplers, one or more delay lines, one or more phase shifters, the like, or any suitable combination thereof. The other circuitry 203 can be electrically connected to the one or more acoustic wave filters 204. The radio frequency module 200 can include one or more packaging structures to, for example, provide protection and/or facilitate easier handling of the radio frequency module 200. Such a packaging structure can include an overmold structure formed over the packaging substrate 206. The overmold structure can encapsulate some or all of the components of the radio frequency module 200.

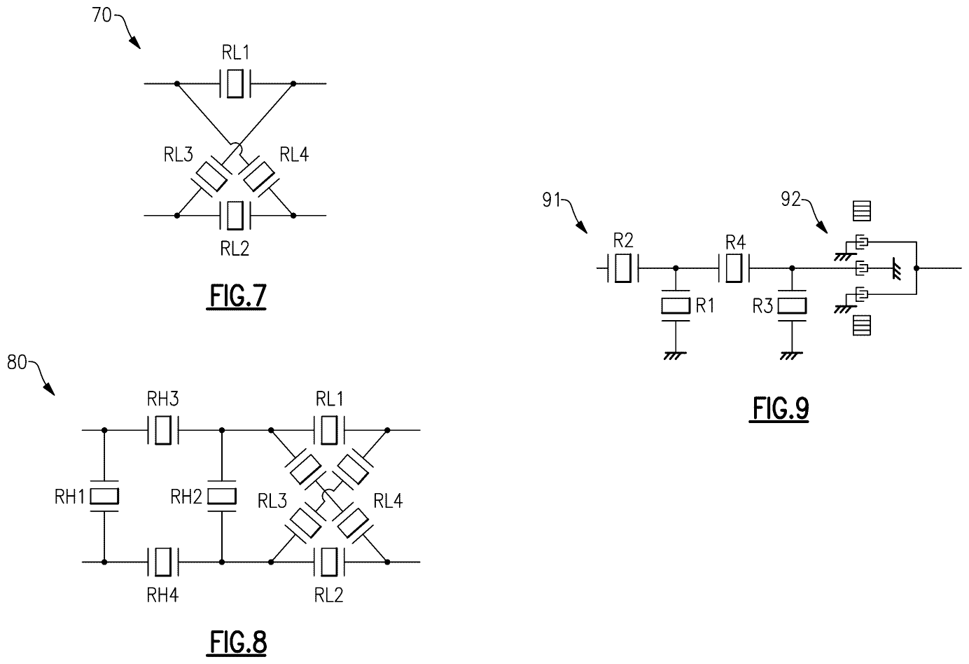

FIG. 12 is a schematic block diagram of a module 210 that includes duplexers 211A to 211N and an antenna switch 212. One or more filters of the duplexers 211A to 211N can include an acoustic wave filter in accordance with any suitable principles and advantages disclosed herein. Any suitable number of duplexers 211A to 211N can be implemented. The antenna switch 212 can have a number of throws corresponding to the number of duplexers 211A to 211N. The antenna switch 212 can include one or more additional throws coupled to one or more filters external to the module 210 and/or coupled to other circuitry. The antenna switch 212 can electrically couple a selected duplexer to an antenna port of the module 210.

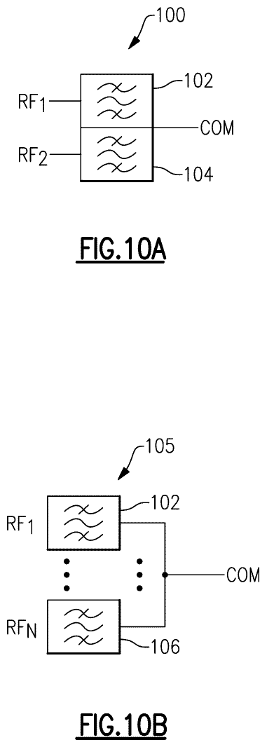

FIG. 13 is a schematic block diagram of a module 220 that includes a power amplifier 222, a radio frequency switch 224, and duplexers 211A to 211N according to an embodiment. The power amplifier 222 can amplify a radio frequency signal. The radio frequency switch 224 can be a multi-throw radio frequency switch. The radio frequency switch 224 can electrically couple an output of the power amplifier 222 to a selected transmit filter of the duplexers 211A to 211N. One or more filters of the duplexers 211A to 211N can be an acoustic wave filter in accordance with any suitable principles and advantages disclosed herein. Any suitable number of duplexers 211A to 211N can be implemented.

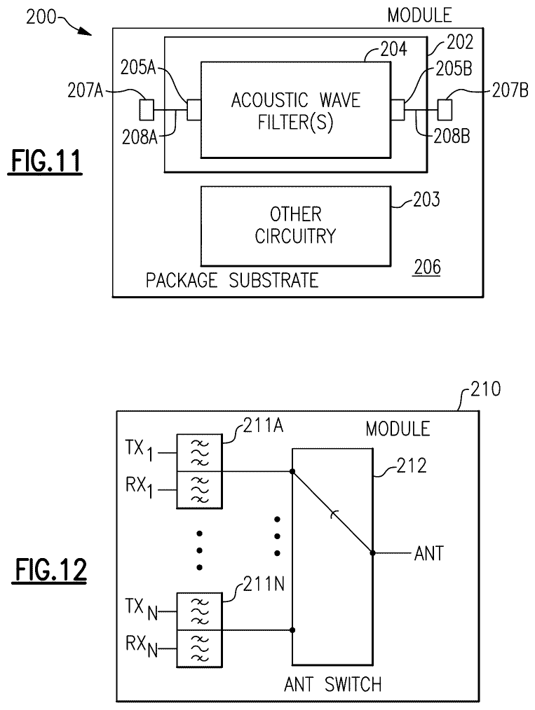

FIG. 14 is a schematic block diagram of a module 230 that includes filters 232A to 232N, a radio frequency switch 234, and a low noise amplifier 236 according to an embodiment. One or more filters of the filters 232A to 232N can include any suitable number of acoustic wave filters in accordance with any suitable principles and advantages disclosed herein. Any suitable number of filters 232A to 232N can be implemented. The illustrated filters 232A to 232N are receive filters. In some embodiments (not illustrated), one or more of the filters 232A to 232N can be included in a multiplexer that also includes a transmit filter. The radio frequency switch 234 can be a multi-throw radio frequency switch. The radio frequency switch 234 can electrically couple an output of a selected filter of filters 232A to 232N to the low noise amplifier 236. In some embodiments (not illustrated), a plurality of low noise amplifiers can be implemented. The module 230 can include diversity receive features in certain applications.

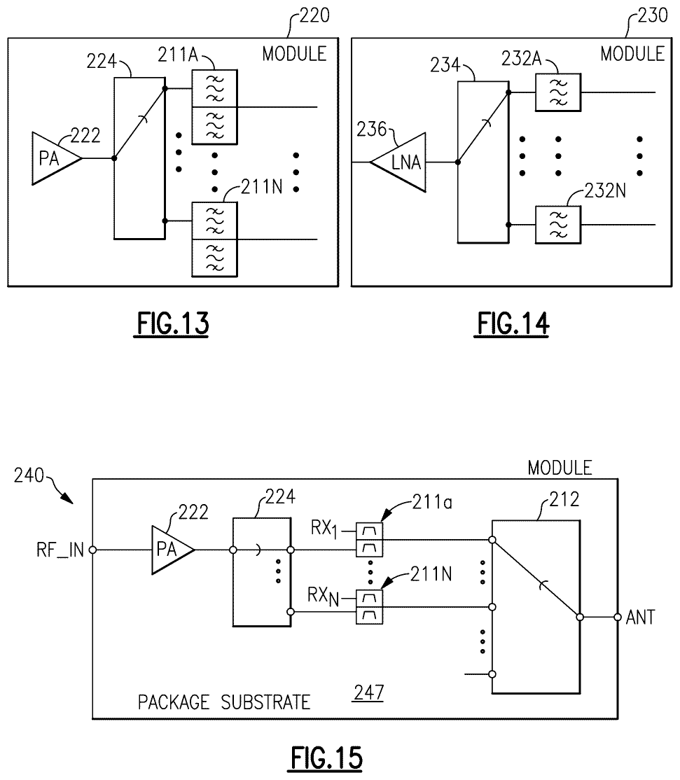

FIG. 15 is a schematic diagram of a radio frequency module 240 that includes an acoustic wave filter according to an embodiment. As illustrated, the radio frequency module 240 includes duplexers 211A to 211N, a power amplifier 222, a select switch 224, and an antenna switch 212. The radio frequency module 240 can include a package that encloses the illustrated elements. The illustrated elements can be disposed on a common packaging substrate 247. The packaging substrate 247 can be a laminate substrate, for example. A radio frequency module that includes a power amplifier can be referred to as a power amplifier module. A radio frequency module can include a subset of the elements illustrated in FIG. 15 and/or additional elements. The radio frequency module 240 may include any one of the acoustic wave filters in accordance with any suitable principles and advantages disclosed herein.

The duplexers 211A to 211N can each include two acoustic wave filters coupled to a common node. For example, the two acoustic wave filters can be a transmit filter and a receive filter. As illustrated, the transmit filter and the receive filter can each be a band pass filter arranged to filter a radio frequency signal. One or more of the transmit filters can include an acoustic wave filter in accordance with any suitable principles and advantages disclosed herein. Similarly, one or more of the receive filters can include an acoustic wave filter in accordance with any suitable principles and advantages disclosed herein. Although FIG. 15 illustrates duplexers, any suitable principles and advantages disclosed herein can be implemented in other multiplexers (e.g., quadplexers, hexaplexers, octoplexers, etc.) and/or in switch-plexers and/or with standalone filters.

The power amplifier 222 can amplify a radio frequency signal. The illustrated switch 224 is a multi-throw radio frequency switch. The switch 224 can electrically couple an output of the power amplifier 222 to a selected transmit filter of the transmit filters of the duplexers 211A to 211N. In some instances, the switch 224 can electrically connect the output of the power amplifier 222 to more than one of the transmit filters. The antenna switch 212 can selectively couple a signal from one or more of the duplexers 211A to 211N to an antenna port ANT. The duplexers 211A to 211N can be associated with different frequency bands and/or different modes of operation (e.g., different power modes, different signaling modes, etc.).

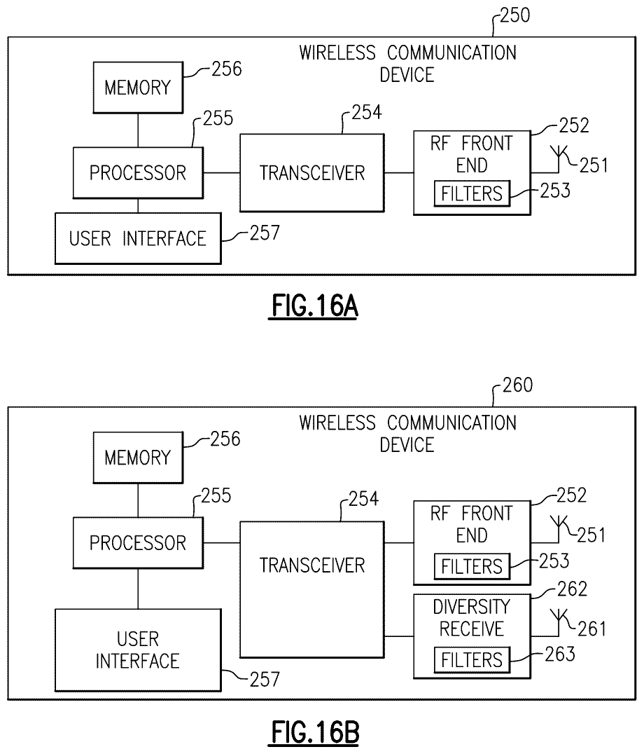

The acoustic wave filters disclosed herein can be implemented in a variety of wireless communication devices. FIG. 16A is a schematic diagram of a wireless communication 250 device that includes filters 253 in a radio frequency front end 252 according to an embodiment. One or more of the filters 253 can be acoustic wave filter in accordance with any suitable principles and advantages disclosed herein. The wireless communication device 250 can be any suitable wireless communication device. For instance, a wireless communication device 250 can be a mobile phone, such as a smart phone. As illustrated, the wireless communication device 250 includes an antenna 251, an RF front end 252, a transceiver 254, a processor 255, a memory 256, and a user interface 257. The antenna 251 can transmit RF signals provided by the RF front end 252. Such RF signals can include carrier aggregation signals. The antenna 251 can receive RF signals and provide the received RF signals to the RF front end 252 for processing. Such RF signals can include carrier aggregation signals. The wireless communication device 250 can include two or more antennas in certain instances.

The RF front end 252 can include one or more power amplifiers, one or more low noise amplifiers, one or more RF switches, one or more receive filters, one or more transmit filters, one or more duplex filters, one or more multiplexers, one or more frequency multiplexing circuits, the like, or any suitable combination thereof. The RF front end 252 can transmit and receive RF signals associated with any suitable communication standards. One or more of the filters 253 can include an acoustic wave filter with two types of acoustic resonators that includes any suitable combination of features of the embodiments disclosed above.

The transceiver 254 can provide RF signals to the RF front end 252 for amplification and/or other processing. The transceiver 254 can also process an RF signal provided by a low noise amplifier of the RF front end 252. The transceiver 254 is in communication with the processor 255. The processor 255 can be a baseband processor. The processor 255 can provide any suitable base band processing functions for the wireless communication device 250. The memory 256 can be accessed by the processor 255. The memory 256 can store any suitable data for the wireless communication device 250. The user interface 257 can be any suitable user interface, such as a display with touch screen capabilities.

FIG. 16B is a schematic diagram of a wireless communication device 260 that includes filters 253 in a radio frequency front end 252 and second filters 263 in a diversity receive module 262. The wireless communication device 260 is like the wireless communication device 250 of FIG. 16A, except that the wireless communication device 260 also includes diversity receive features. As illustrated in FIG. 16B, the wireless communication device 260 includes a diversity antenna 261, a diversity module 262 configured to process signals received by the diversity antenna 261 and including filters 263, and a transceiver 254 in communication with both the radio frequency front end 252 and the diversity receive module 262. One or more of the second filters 263 can include an acoustic wave filter in accordance with any suitable principles and advantages disclosed herein.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes example embodiments, the teachings described herein can be applied to a variety of structures. Any of the principles and advantages discussed herein can be implemented in association with RF circuits configured to process signals having a frequency in a range from about 30 kHz to 300 GHz, such as in a frequency range from about 400 MHz to 8.5 GHz.

An acoustic wave filter including any suitable combination of features disclosed herein be arranged to filter a radio frequency signal in a 5GNR operating band within Frequency Range 1 (FR1). A filter arranged to filter a radio frequency signal in a 5G NR operating band can include two types of acoustic resonators in accordance with any principles and advantages disclosed herein. FR1 can be from 410 MHz to 7.125 GHz, for example, as specified in a current 5G NR specification. In 5G applications, an acoustic wave filter with a relatively wide pass band and relatively low insertion loss can be advantageous for implementing dual connectivity. An acoustic wave filter in accordance with any suitable principles and advantages disclosed herein can be arranged to filter a radio frequency signal in a 4G LTE operating band and/or in a filter having a passband that includes a 4G LTE operating band and a 5G NR operating band. Filters disclosed herein can filter radio frequency signals in a frequency range from about 400 MHz to 3 GHz in certain applications.

Aspects of this disclosure can be implemented in various electronic devices. Examples of the electronic devices can include, but are not limited to, consumer electronic products, parts of the consumer electronic products such as packaged radio frequency modules, radio frequency filter die, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a robot such as an industrial robot, an Internet of things device, a stereo system, a digital music player, a radio, a camera such as a digital camera, a portable memory chip, a home appliance such as a washer or a dryer, a peripheral device, a wrist watch, a clock, etc. Further, the electronic devices can include unfinished products.

Unless the context indicates otherwise, throughout the description and the claims, the words “comprise,” “comprising,” “include,” “including” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. The word “coupled”, as generally used herein, refers to two or more elements that may be either directly coupled, or coupled by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

While certain embodiments have been described, these embodiments have been presented by way of example only, and are not intended to limit the scope of the disclosure. Indeed, the novel resonators, filters, multiplexer, devices, modules, wireless communication devices, apparatus, methods, and systems described herein may be embodied in a variety of other forms. Furthermore, various omissions, substitutions and changes in the form of the resonators, filters, multiplexer, devices, modules, wireless communication devices, apparatus, methods, and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and/or acts of the various embodiments described above can be combined to provide further embodiments. The accompanying claims and their equivalents are intended to cover such forms or modifications as would fall within the scope and spirit of the disclosure.

What is claimed is:

1. A chip scale package comprising
a substrate;
a cavity formed in or above the substrate; and
a cavity roof comprising a filler material and having a low coefficient of thermal expansion in a range between 0 and 30 ppm/degree (ppm/°).

2. The chip scale package of claim 1 wherein the substrate includes a Silicon (Si) substrate.

3. The chip scale package of claim 1 wherein the cavity roof includes a layer of a polymer with the filler material.

4. The chip scale package of claim 1 wherein the cavity roof has a Young modulus in a range between 5 and 30 Terapascal (TPa).

5. The chip scale package of claim 1 wherein the chip scale package includes a cavity wall and an acoustic wave device including a piezo layer and a functional layer, the cavity wall being separated from the piezo layer and the functional layer.

6. The chip scale package of claim 5 wherein the chip scale package includes a cavity pillar.

7. The chip scale package of claim 6 further including a Cu via formed at or through the cavity wall.

8. The chip scale package of claim 1 further including a metal 2 (M2) layer arranged as a mechanical clamp to avoid delamination of a piezo layer, a functional layer, or both.

9. The chip scale package of claim 1 wherein the chip scale package includes a Cu layer formed on the cavity roof.

10. The chip scale package of claim 1 wherein Cu vias extending through different layers of the chip scale package are at least pairwise relatively arranged along a straight line.

11. A method of forming a chip scale package comprising:
forming a substrate;
forming a cavity in or above the substrate; and
forming a cavity roof including a filler material and having a low coefficient of thermal expansion in a range between 0 and 30 ppm/degree (ppm/°).

12. The method of claim 11 wherein the substrate includes a Silicon (Si) substrate.

13. The method of claim 11 wherein the cavity roof includes a layer of a polymer with the filler material.

14. The method of claim 11 wherein the cavity roof has a Young modulus in the range between 5 and 30 Terapascal (TPa).

15. A surface acoustic wave filter package comprising:
a substrate;
a cavity formed in or above the substrate;
one or more surface acoustic wave filters formed on the substrate; and
a cavity roof including a filler material and having a low coefficient of thermal expansion in a range between 0 and 30 ppm/degree (ppm/°).

16. The surface acoustic wave filter package of claim 15 wherein the substrate includes a Silicon (Si) substrate.

17. The surface acoustic wave filter package of claim 15 wherein the cavity roof has a coefficient of thermal expansion in a range between 0 and 30 ppm/degree (ppm/°).

18. The surface acoustic wave filter package of claim 15 wherein the cavity roof has a Young modulus in a range between 5 and 30 Terapascal (TPa).

19. The surface acoustic wave filter package of claim 15 wherein the surface acoustic wave filter package includes a cavity wall, a piezo layer, and a functional layer, the cavity wall being separated from the piezo layer and the functional layer.

20. A mobile device comprising a multiplexer including the surface acoustic wave filter package of claim 15.
